(19) United States
(12) Patent Application Publication
(10) Pub. No.: US 2026/0213145 A1
(43) Pub. Date: Jul. 23, 2026

(54) SYSTEM AND METHOD FOR ENDPOINT DETECTION

(71) Applicant: Tokyo Electron Limited, Tokyo (JP)

(72) Inventors: Sergey Voronin, Albany, NY (US); Nicholas Smieszek, Albany, NY (US); Qi Wang, Albany, NY (US); Blaze Messer, Albany, NY (US); Hwang-Jye Yang, Fremont, CA (US); Shuyan Zhang, Fremont, CA (US); Joel Ng, Fremont, CA (US); Holger Tuitje, Fremont, CA (US); Yan Chen, Fremont, CA (US); Pingshan Luan, Albany, NY (US); Shihsheng Chang, Albany, NY (US); Akiteru Ko, Albany, NY (US); Ying Zhu, Fremont, CA (US); Ivan Maleev, Fremont, CA (US); Ashawaraya Shalini, Fremont, CA (US); Francisco Machuca, Fremont, CA (US)

(21) Appl. No.: 19/028,192

(22) Filed: Jan. 17, 2025

(51) Int. Cl. H01J 37/32

(52) U.S. Cl. CPC H01J 37/32972; H01J 37/32357; H01J 37/32963; H01J 2237/3321; H01J 2237/3341

(57) ABSTRACT

A system and method for endpoint detection is provided based on hyperspectral imaging technology and the exhaust gas chamber from a semiconductor processing chamber. The system includes a processing chamber that holds a substrate for processing. An exhaust gas line connects to an exhaust outlet of the processing chamber and directs exhaust gas to an exhaust chamber. A first RF power source connects to the exhaust chamber and generates an exhaust plasma from a portion of the exhaust gas within the exhaust chamber. A hyperspectral imaging (HSI) camera measures hyperspectral images of the exhaust plasma in the exhaust chamber. A method of processing the HSI images for endpoint detection is described.

### TECHNICAL FIELD

The present invention relates generally to systems and methods of characterization, and, in particular embodiments, to hyperspectral imaging (HSI) system for endpoint detection.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Process flows used to form the constituent structures of semiconductor devices often involve depositing and removing a variety of materials while a pattern of several materials may be exposed in a surface of the working substrate.

Advanced process control that involves process and system characterization and fault detection in semiconductor manufacturing is essential for reproducible production of complex structures. Especially in high-volume manufacturing, plasma system monitoring is of paramount importance for process consistency. As the minimum dimension of features in a patterned layer has shrunk periodically and new materials have been introduced in ICs, the need for improved plasma system monitoring to assure process compliance and cost reduction has increased.

### SUMMARY

In accordance with one aspect of the present invention, a processing system is provided for treating exhaust gas from a semiconductor processing chamber. The system includes a processing chamber for holding a substrate, with an exhaust gas line connected to an exhaust outlet of the processing chamber. An exhaust chamber connects to the exhaust gas line. A first RF power source connects to the exhaust chamber and generates an exhaust plasma from exhaust gas within the exhaust chamber. A hyperspectral imaging (HSI) camera measures hyperspectral images of the exhaust plasma in the exhaust chamber.

In accordance with another aspect of the present invention, a method is provided for processing a substrate. The method includes processing a substrate in a processing chamber and removing exhaust gas from the processing chamber through an exhaust gas line. An exhaust plasma is generated in an exhaust chamber that connects to the processing chamber via the exhaust gas line. A hyperspectral image is detected from the exhaust plasma using an HSI camera. Endpoint detection (EPD) of the substrate processing is performed based on the hyperspectral image.

In accordance with yet another aspect of the present invention, a method is provided for endpoint detection based on hyperspectral imaging. The method includes performing a survey scan of a hyperspectral image across a full wavelength range before and after endpoint of the plasma process to establish a baseline spectral database or optical emission spectroscopy (OES). At least one wavelength is selected for endpoint detection based on survey scan results. To boost the signal-to-noise ratio (SNR) for EPD, hyperspectral images are collected at the selected wavelength(s) over time during plasma processing, so that the frame rate is the highest for SNR calculation, and the process endpoint is detected based on changes in the intensity change at the selected wavelength(s). In addition, a ratio of intensities between two wavelengths could be used as the figure of merit, and the endpoint could be detected using the change of the ratio as a function of time.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a processing system with endpoint detection (EPD), in accordance with an embodiment;

FIG. 2 illustrates components of an example hyperspectral imaging (HSI) camera, in accordance with an embodiment;

FIG. 3 illustrates an example process flow chart of EPD method based on analyzing hyperspectral images from a processing chamber, in accordance with an embodiment;

FIG. 4 illustrates an example process flow chart of EPD method based on analyzing hyperspectral images from an exhaust chamber, in accordance with an embodiment;

FIGS. 5a-5b illustrate an example process flow chart of processing hyperspectral images in an EPD method and exemplary data illustrating intensities of selected wavelengths over time, in accordance with an embodiment;

FIG. 6 illustrates an example process flow chart of method for enhancing signal-to-noise ratio (SNR) of hyperspectral images, in accordance with an embodiment; and

FIGS. 7a-7c illustrate experimental data of analyzing SNR values across different pixels of hyperspectral image, in accordance with an embodiment.

### DETAILED DESCRIPTION OF ILLUSTRATIVE EMBODIMENTS

This application relates to systems and methods of process characterization, more particularly to hyperspectral imaging (HSI) method for advanced process characterization. In semiconductor manufacturing, plasma processing is used at various stages for depositing and etching various materials to construct complex structures with precision at nanometer scale. Optical emission spectroscopy (OES) has been traditionally applied to analyze atoms and ions present in a plasma by detecting optical emission from excited species, thereby performing endpoint detection (EPD) of a plasma etch process such as reactive ion etching (RIE).

However, depending on the types of materials being processed and the process parameters, some process conditions require very weakly ionized or even no plasma discharge, leading to limited sensitivity of OES due to insufficient excitation for optical emissions. New methods with improved sensitivity are therefore desired for advanced process characterization, especially in weakly ionized plasma or plasma-less processes.

Embodiments of the present application disclose improved systems and methods for EPD based on HSI during a semiconductor processing, in which an additional plasma source may be introduced for additional hyperspectral image collection. The additional plasma source may be used to generate an additional plasma external to a processing chamber, particularly in an exhaust system downstream from the processing chamber. The additional hyperspectral image, alone or in combination with the hyperspectral image from processing chamber, may be used for various types of process characterization such as process monitoring and endpoint detection (EPD). The use of additional plasma source may improve the sensitivity of HSI during a process, particularly beneficial for advanced 3D device fabrication where endpoints are characterized by subtle plasma fluctuations.

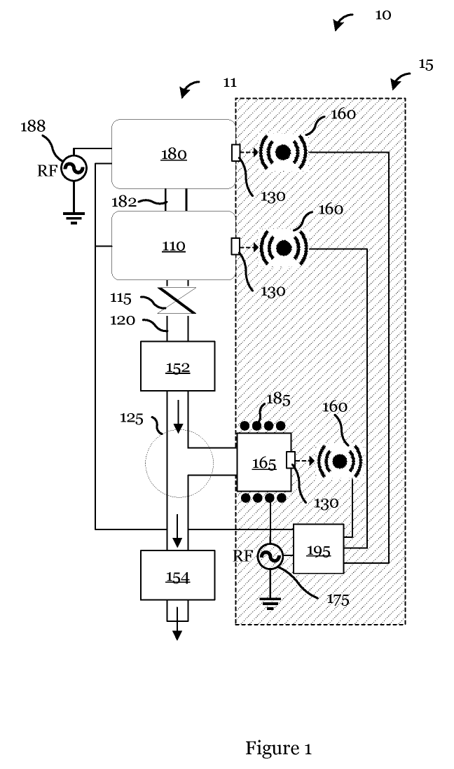

FIG. 1 illustrates an example processing system 10 integrating an HSI assembly 15 to perform EPD, in accordance with an embodiment.

In FIG. 1, the processing system 10 may comprise a plasma processing system 11 and an HSI measurement assembly 15. In various embodiments, the plasma processing system 11 may be configured to process a substrate with a processing plasma or reactive gas in a processing chamber 110, for example, as a part of semiconductor device fabrication. The processing system 10 may accordingly be configured to perform process characterization of the process performed by the plasma processing system 11. In various embodiments, the plasma processing system 11 may apply a plasma to process a substrate, but various types and configurations for the plasma processing system 11 including a low-powered plasma, or plasma-less processing system are possible. For illustration purpose, various elements of the plasma processing system 11 that may be present (e.g., gas inlets, plasma power supply, electrodes, substrate holder, transfer ports, etc.) are omitted in FIG. 1.

As illustrated in FIG. 1, the plasma processing system 11 may comprise an exhaust gas line 120 connected to the processing chamber 110. A throttle valve 115 may be used as a part of a vacuum system to control the pressure of the processing chamber 110. Although only one throttle valve is illustrated at an upstream portion of the exhaust gas line 120 in FIG. 1, more throttle valves may be used at any reasonable position of the vacuum system. The processing chamber 110 may further comprise a transparent viewport 130, configured to enable transmission of hyperspectral images within the processing chamber 110 to an externally mounted camera, for example, an HSI camera 160. In various embodiments, the transparent viewport 130 may comprise optically transparent materials suitable for transmitting hyperspectral images, such as quartz, sapphire, glass, or other similar materials that provide sufficient optical transmission in the desired wavelength range. The transparent viewport 130 may be configured in various shapes, such as circular, rectangular, honeycomb, or other geometric configurations.

The processing chamber 110 may be configured to accommodate both plasma based and non-plasma based fabrication processes. It may be configured as a capacitively coupled plasma (CCP) system or an inductively coupled plasma (ICP) system for etching or deposition applications. In some embodiments, the processing chamber 110 may be applied for plasma etching processes comprising reactive ion etching (RIE), atomic layer etching (ALE), deep reactive ion etching (DRIE), or the like. In some embodiments, the processing chamber 110 may be applied to plasma-assisted atomic layer deposition (ALD) or plasma-enhanced chemical vapor deposition (PECVD) for thin film deposition at lower temperatures. In other embodiments, the processing chamber 110 may be applied to non-plasma fabrication processes comprising conventional chemical vapor deposition (CVD), atomic layer deposition or thermal deposition.

A vacuum system for the plasma processing system 11 may comprise a first vacuum pump 152 and a second vacuum pump 154, both connected to the processing chamber 110 via the exhaust gas line 120 such that the second vacuum pump 154 is disposed downstream from the first vacuum pump 152. In various embodiments, the first vacuum pump 152 may be a turbomolecular pump. In certain embodiments, the pressure in the portion of the exhaust gas line 120 between the two pumps may be between 1 mTorr and 10 Torr.

As illustrated in FIG. 1, the HSI measurement assembly 15 may comprise an exhaust chamber 165 that is connected to the exhaust gas line 120 via a tee conduit 125 disposed between the first vacuum pump 152 and the second vacuum pump 154. Although the positioning of the exhaust chamber 165 may not be limited to any particular location, placing the exhaust chamber 165 to this particular portion of the exhaust gas line 120 downstream from the processing chamber 110 (i.e., between the first vacuum pump 152 and the second vacuum pump 154) may be mechanically more feasible compared to other locations due to limited space. In various embodiments, an exhaust plasma may be generated from the exhaust gas in the exhaust chamber 165 and its hyperspectral images may be measured by additional HSI camera 160 through additional transparent viewport 130. Although not illustrated in FIG. 1, the exhaust chamber 165 may further be connected to any elements that may be useful for sustaining the exhaust plasma (e.g., throttle valve, additional gas inlet, and additional gas outlet.

In one or more embodiments, the exhaust chamber 165 may be equipped with a temperature controller (e.g., heating/cooling system). In one embodiment, the temperature in the exhaust gas line 120 and/or the exhaust chamber 165 may be kept relatively high to prevent residual by-product accumulation on the surfaces.

Disposing the exhaust chamber 165 between the first vacuum pump 152 and the second vacuum pump 154 may advantageously benefit the practicality for generating the exhaust plasma in several aspects. First, the pressure may be maintained low as suitable for a gas discharge for the exhaust plasma. Excitation of the exhaust gas further downstream from the processing chamber 110, for example, after the second vacuum pump, would be more difficult and impractical due to higher pressure environment. Second, the proximity of the exhaust chamber 165 to the processing chamber 110 may minimize the delay of hyperspectral images responsive to an event (e.g., endpoint or process failure) in the processing chamber 110.

A first RF power source 175 may be used as a power supply for generating the exhaust plasma, and a plasma coupler 185 may be disposed outside the walls of the exhaust chamber 165. Although not specifically illustrated, any RF power source (e.g., the first RF power source 175) may comprise a power generator, an amplifier, a function generator, and a matching network. In addition, embodiments may include additional power sources to the exhaust chamber 165. For example, a reference or ground electrode may also be introduced and coupled to a reference potential node or DC power supply node.

The plasma coupler 185 may be a conductive helix coiled horizontally around the walls comprising a dielectric (e.g., a ceramic material). The plasma coupler 185 may alternatively be shaped like a planar coil. The plasma coupler 185 is coupled to the RF power source 175. In various embodiments, the oscillation frequency of the RF power may be about 400 kHz to about 5 GHz and, in certain embodiment about 15 MHz to about 200 MHz. In one embodiment, the frequency of the RF power may be between 20 MHz to 40 MHz, for example 27 MHz. When a resonator helical coil is used for the plasma coupler 185, the frequency may be selected in consideration of the coil length such that the coil may sufficiently surround the walls of the exhaust chamber 165. The plasma coupler 185 may be configured to operate in a purely inductively or capacitively coupled mode to sustain the exhaust plasma with an RF power density of about 0.01 W/cm³ to about 30 W/cm³ within the exhaust chamber 165. In one embodiment, the RF power source may be operated in pulsing mode with a peak power up to about 1000 W/cm³.

In some embodiments, the exhaust chamber 165 may comprise another transparent viewport 130, enabling transmission of hyperspectral images from the exhaust chamber 165 to an HSI camera 160. In various embodiments, the hyperspectral images from the exhaust chamber 165 may be analyzed for plasma diagnostics. In some embodiments, the plasma diagnostics may include monitoring plasma intensity distributions, detecting plasma uniformity variations, analyzing emission spectra of plasma species, measuring plasma density fluctuations, or identifying chemical species present in the plasma. These diagnostic capabilities enable process optimization, fault detection, and quality control during plasma processing operations.

In some embodiments, the plasma processing system 11 may further comprise a remote chamber 180. In some embodiments, the remote chamber 180 may be coupled to the processing chamber 110 through a gas line 182. In alternative embodiments, the remote chamber 180 may be directly attached to the processing chamber 110 through a segregation barrier comprising a mesh, or the like. A second RF power source 188 may be coupled to the remote chamber 180 and configured to generate a remote plasma within the remote chamber 180. In some embodiments, the generated remote plasma may be removed from the remote chamber 180 and introduced into the processing chamber 110 to process the substrate. The plasma generation in the remote chamber 180 allows for pre-dissociation of process gases and creation of reactive species before they reach the substrate in the processing chamber 110. By separating plasma generation from the immediate vicinity of the substrate, this approach may reduce potential damage from ion bombardment while still provide the benefits of plasma-activated chemistry. Additionally, it offers greater flexibility in tailoring the plasma chemistry for specific applications, such as PECVD or specialized etching processes, thereby enabling precise control over the types and concentrations of reactive species.

In some embodiments, the remote chamber 180 may comprise additional transparent viewport 130, configured to transmit hyperspectral images from the remote chamber 180 to additional HSI camera 160. In various embodiments, the hyperspectral images from the remote chamber 180 may be analyzed for plasma diagnostics. In some embodiments, the plasma diagnostics may include monitoring plasma intensity distributions, detecting plasma uniformity variations, analyzing emission spectra of plasma species, measuring plasma density fluctuations, or identifying chemical species present in the plasma. These diagnostic capabilities enable process optimization, fault detection, and quality control during plasma processing operations.

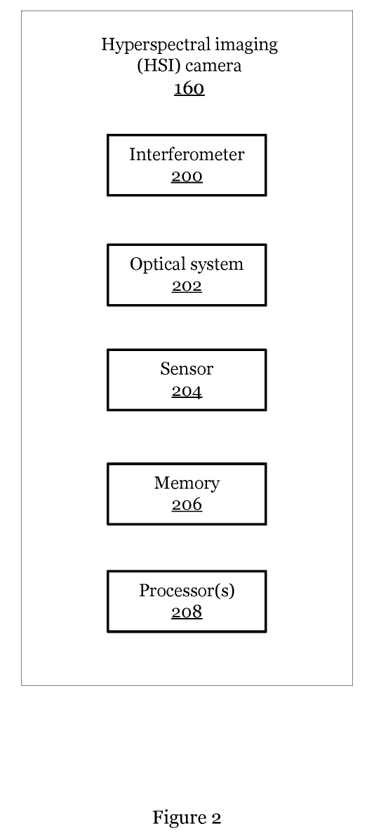

The HSI camera 160 may comprise various electrical and optical components required to perform detection, recording, and analysis of the hyperspectral images from the processing plasma or the exhaust plasma. FIG. 2 illustrates components of the HSI camera 160, in accordance with an embodiment.

The HSI camera 160 may comprise an interferometer 200, an optical system 202, a sensor 204, a memory 206, and processor(s) 208. In various embodiments, the HSI camera 160 may be configured to receive a command from a controller 195 (FIG. 1) and perform a series of operations accordingly: filtering wavelengths of hyperspectral images with the interferometer 200, focusing and directing the filtered hyperspectral images through the optical system 202, detecting and converting hyperspectral images to digital data through the sensor 204, recording and storing the digital data on the memory 206, and processing the digital data with the processor(s) 208 through executable program stored in the memory 206.

The interferometer 200 may be a tunable Fabry-Pérot interferometer or an acousto-optic tunable filter (AOTF) or a liquid crystal tunable filter or a Michelson interferometer for selective wavelength filtering. In some embodiments, the interferometer 200 may comprise a frequency generator, a piezoelectric actuator, and integrated suite of electronic components including a high-resolution analog-to-digital converter (ADC), digital signal processor (DSP), and communication interfaces for robust signal generation, acquisition, processing, and data transmission. The frequency generator may produce the electrical signals necessary to modulate the interferometer's gap, while the piezoelectric actuator controls the physical movement of the reflective surfaces. In some embodiments, the interferometer 200 may operate in a free-run scanning mode, dynamically varying the distances between reflective surfaces to capture a wider range of wavelengths across hyperspectral images. This mode allows for comprehensive hyperspectral image collection and analysis, providing detailed information into the plasma at a wide wavelength range. Alternatively, the interferometer 200 may operate in a fixed gap non-scanning mode, maintaining a constant distance between reflective surfaces to target specific wavelengths of hyperspectral images with high accuracy. This configuration ensures stable and focused transmitted intensity at chosen wavelengths, ideal for precise monitoring tasks. The dual-mode functionality of the interferometer 200 offers the HSI camera 160 a versatile solution for both broad-spectrum and targeted applications.

In some embodiments, the optical system 202 may comprise a plurality of lenses and mirrors and configured to focus and direct incoming hyperspectral images to optimize signal path efficiency and image clarity. For example, a converging lens may initially focus the dispersed light signals, while strategically positioned mirrors redirect the path to align with the sensor array as described in detail below. Adjustable tilts and angles ensure optimal focus across the full spectrum of received signals. The hyperspectral images from the first or the exhaust plasma may encompass both spatial and spectral information that can be used to analyze spatial distribution and uniformity of the plasmas. The optical system 202 ensures that these complex signals are accurately transmitted to subsequent components, facilitating detailed examination and interpretation.

In some embodiments, the sensor 204 may be configured to convert received hyperspectral images to digital data, which may include light intensity as a function of wavelength across different spatial pixels. The sensor 204 may comprise a plurality of charge-coupled device (CCD) sensors, complementary metal-oxide-semiconductor (CMOS) image sensors, or other advanced photosensors. These components are capable of measuring light intensity at each pixel from the processing chamber 110 or the exhaust chamber 165. In certain embodiments, the sensor 204 may comprise a CCD sensor with a capability of millisecond time resolution to capture dynamic plasma changes. In another embodiment, the sensor 204 may comprise a CMOS image sensor with a high temporal resolution in microsecond.

In some embodiments, the signal from the sensor 204 may be processed through an amplifier to increase signal strength while maintaining signal fidelity. In some embodiments, an analog-to-digital converter (ADC) may convert the amplified analog signals into discrete digital values. In one or more embodiments, a processor may interface with the ADC to receive and process the digital spectral data, which may include light intensity as a function of wavelength across different spatial pixels.

In various embodiments, the memory 206 may be a non-transitory memory configured to record and store the digital data and a program comprising instructions which are executed by one or more processors 208 to perform the various functions described herein. For example, the memory 206 may generally include both volatile memory and non-volatile memory, for example, random access memory (RAM), read only memory (ROM), or the like. The memory 206 is capable of storing computer-readable, processor-executable program instructions as computer program code that may be executed by the processor(s) 208 as a particular machine configured for carrying out the operations and functions described in the implementations herein.

In some embodiments, the hyperspectral images detected by the HSI camera 160 include comprehensive spatial and spectral information, distinguishing them from traditional methods like spectrometers and white light color cameras (or multiple wavelength RGB cameras). Unlike these methods, which focus on limited spatial dimensions, for example, one dimension, or limited wavelength channels, for example, tens of wavelength channels, HSI captures a full spectrum for each pixel, offering a complete view of both spatial uniformity and spectral characteristics. In various embodiments, HSI may simultaneously acquire full spatial and spectral information across hundreds to thousands of wavelength channels, offering improved resolution. This capability is particularly advantageous for EPD as it allows monitoring based on changes in plasma uniformity across a remote plasma volume, rather than solely on wavenumber intensity.

The spatial information in hyperspectral images enables the detection of uniformity changes and provides insights into the chemical species present in the gas or plasma through identifying unique spectral signatures associated with these chemical species. For example, the HSI camera 160 may be configured to detect various chemical species including halides of silicon and the halogen species itself (e.g. chlorine, fluorine, and bromine). In some embodiments, the plasma processing may comprise etching of silicon oxide using a fluorine-containing chemistry, such as a fluorocarbon or hydrofluorocarbon gas. In such embodiments, it is useful to dynamically detect halides of silicon and the halogen species that are released by the decomposition of the fluorocarbon or hydrofluorocarbon gas in order to monitor the etch process for its process and stability. Other detectable byproducts may include carbon monoxide, and carbon dioxide, formed by reaction of oxygen from a film or gas mixture with carbon from the fluorocarbon or hydrofluorocarbon gas.

Referring back to FIG. 1. In various embodiments, the HSI measurement assembly 15 may further comprise the controller 195 coupled to the HSI cameras 160, the processing chamber 110, the remote chamber 180, and the first RF power source 175.

Although not specifically illustrated, the controller 195 may comprise various electrical components such as memories and processors to process the data from the HSI cameras 160 and perform feedback control of the plasma processing system 11 and the HSI measurement assembly 15. For example, a non-transitory memory may store a program to be executed in the controller 195, wherein the program comprises instructions, when executed by the controller 195, enabling the controller to perform an EPD of a process in the processing chamber 110 based on the detected hyperspectral images.

In various embodiments, the HSI measurement assembly 15 may be configured to perform a series of operations according to a command from the controller 195: selecting the HSI camera 160 to receive hyperspectral images from the remote chamber 180, the processing chamber 110, or the exhaust chamber 165, adjusting the outputs of the first RF power source 175, and determining a characteristic of the gas or plasma. The characteristic of the plasma may, for example, be plasma uniformity, and/or concentrations of reactive ion species, etch by-product, or other species of interest. The characteristic of the plasma may also include information on electron temperature. The characteristic of the gas may include gas composition and species concentrations, presence and levels of impurities or contaminants, dissociation rates of molecular gases, or other species of interest. In certain embodiments, the HSI measurement assembly 15 may be further configured to process the detected hyperspectral image by the HSI camera 160, for example, averaging and/or filtering prior to determining the characteristic of the gas or plasma.

In some embodiments, the plasma processing system 11 may be configured to perform a series of operations according to a command from the controller 195: adjusting the power of the RF power sources or species in the processing chamber 110 or the remote chamber 180 to control the plasma processing, adjusting the vacuum pumps (e.g., the first pump 152 or the second pump 154) to control the concentration of exhaust plasma in the exhaust chamber 165.

In various embodiments, the memory of the controller 195 may comprise a non-transitory memory storing a program which are executed by the processor to perform the various functions described herein. For example, the memory may generally include both volatile memory and non-volatile memory (e.g., RAM, ROM, or the like). The memory may be referred to as memory or computer-readable storage media herein. The memory is capable of storing computer-readable, processor-executable program instructions as computer program code that may be executed by the processors of the controller 195 as a particular machine configured for carrying out the operations and functions described in the implementations herein.

Although the description of this disclosure is focused on the HSI assembly 15 with three sources of hyperspectral images, the systems and methods may be applicable to single or more than three source(s). For example, in one embodiment, the HSI measurement assembly 15 may be solely configured to detect the hyperspectral image from the processing chamber 110. In another embodiment, the HSI measurement assembly 15 may be solely configured to detect the hyperspectral image from the exhaust chamber 165. In other embodiments, additional source of hyperspectral images (e.g., collecting two hyperspectral images from two different regions of the exhaust chamber 165 or the processing chamber 110) may be introduced.

Furthermore, by detecting the hyperspectral image of the exhaust plasma in the exhaust chamber 165, it is possible to monitor subtle fluctuations in the characteristics of the processing plasma in the processing chamber 110. In some embodiments, a high discharge power may be applied by the first RF power source 175 to generate the exhaust plasma, resulting in amplified plasma fluctuations and enhanced hyperspectral image intensity. This augmented intensity difference increases the HSI's sensitivity to detect minor uniformity changes associated with plasma process endpoints. Such enhanced sensitivity is particularly advantageous in advanced 3D device fabrication, where endpoint signals may be inherently weak or obscured by background plasma emissions.

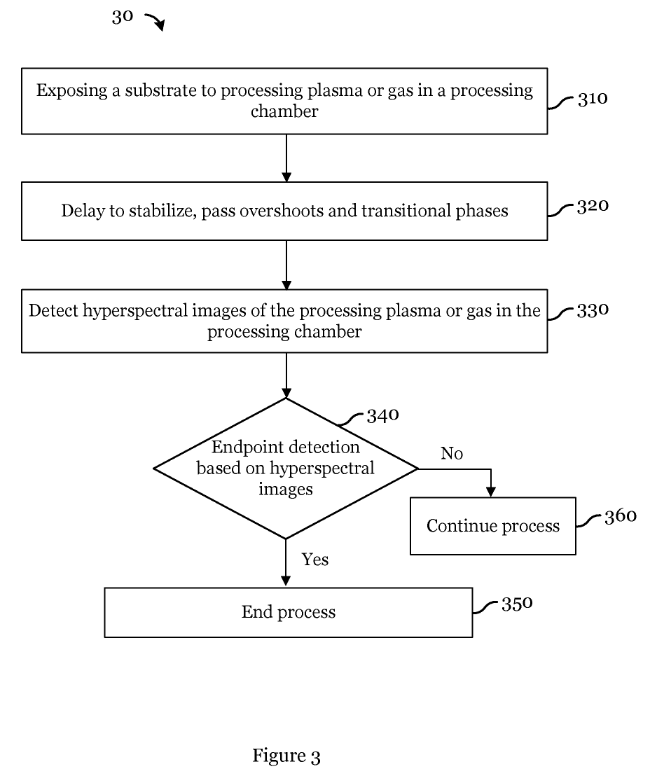

FIG. 3 illustrates an example process flow chart of EPD method based on analyzing hyperspectral images of processing plasma or gas in the processing chamber 110, in accordance with an embodiment.

In FIG. 3, a process flow 30 may start with a processing of a substrate in the processing chamber 110 by exposing the substrate to a processing plasma or gas (block 310). The substrate may comprise a bulk substrate such as a blank silicon wafer, a silicon-on-insulator (SOI) wafer, or any of various other semiconductor substrates. The substrate may also be coated or layered with any number of additional materials, including compound semiconductors, metal or metal oxides, or metal nitrides. The substrate may include any material portion or structure of a device, particularly a semiconductor or other electronics device.

In some embodiments, the plasma for processing the substrate may be initially generated in the remote chamber 180 and related reactive species may be introduced into the processing chamber 110. In some embodiments, the processing of the substrate may be conducted without plasma, utilizing non-plasma techniques. This configuration allows for a variety of thermal, chemical, or physical vapor deposition processes that do not require plasma activation, such as conventional chemical vapor deposition (CVD), atomic layer deposition (ALD), or thermal annealing treatments.

Afterwards, a delay period is introduced to allow for stabilization, passing overshoots and transitional phases during the processing of the substrate (block 320). This delay period ensures that the process reaches a stable state, minimizing fluctuations that may lead to inaccurate data collection and analysis.

After delay period, the detection of hyperspectral images may start (block 330). The hyperspectral images of the processing plasma or gas in the processing chamber 110 may be transmitted to the HSI camera 160 through the transparent viewport 130. The hyperspectral images may be recorded, stored and processed, based on which temporal changes of the characteristic of the processing plasma may be estimated (block 340). In one embodiment, the HSI camera 160 may continuously detect the hyperspectral image over a period of time of the processing of the substrate. In another embodiment, the HSI camera 160 may periodically detect the hyperspectral image over a period of time of the processing of the substrate. If the characteristic changes indicate the EPD, the controller 195 may communicate with the processing chamber 110 to end the processing of the substrate (block 350). If the endpoint is not detected, the processing of the substrate may continue (block 360).

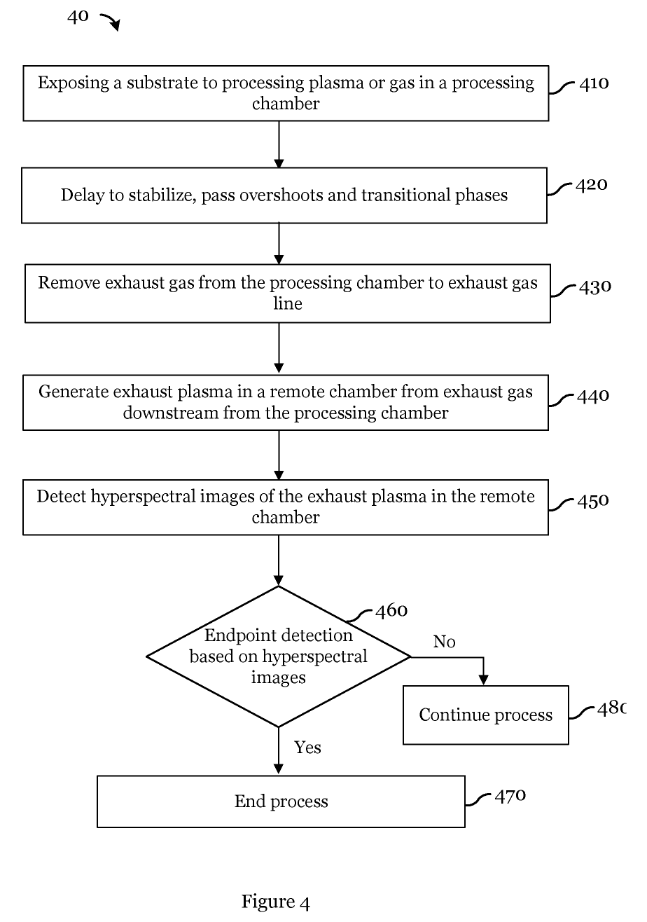

FIG. 4 illustrates an example process flow chart of EPD method based on analyzing hyperspectral images of exhaust plasma in the exhaust chamber 165, in accordance with an embodiment.

In FIG. 4, a process flow 40 may start with the processing of the substrate in the processing chamber 110 by exposing the substrate to a processing plasma or gas (block 410). The substrate may comprise the same materials, components, or structures of the substrate as described in block 310. In some embodiments, the plasma for processing the substrate may be initially generated in the remote chamber 180 and related reactive species may be subsequently introduced into the processing chamber 110 via the gas line 182. In some embodiments, the processing of the substrate may be conducted without plasma, utilizing non-plasma techniques.

Following this, a delay period is introduced to allow for stabilization, passing overshoots and transitional phases during the processing of the substrate (block 420). This delay period ensures that the process reaches a stable state, minimizing fluctuations that may lead to inaccurate data collection and analysis.

Afterwards, exhaust gas may be removed from the processing chamber 110 to the exhaust gas line 120 (block 430). As the exhaust gas enters the exhaust chamber 165, the first RF power source 175 may be activated to generate the exhaust plasma in the exhaust chamber 165 (block 440). The characteristic changes of the processing plasma may be amplified by the generated exhaust plasma, enabling higher sensitivity of the HSI camera in plasma characterization.

In block 450, detection of hyperspectral images of the exhaust plasma may start. The HSI camera 160 may receive the images of the exhaust plasma in the exhaust chamber 165 through the transparent viewport 130. The hyperspectral images may be recorded, stored and processed, enabling estimation of temporal changes in the characteristics of the exhaust plasma (block 460). In one embodiment, the HSI camera 160 may continuously detect the hyperspectral image over a period of time of the processing of the substrate. In another embodiment, the HSI camera 160 may periodically detect the hyperspectral image over a period of time of the processing of the substrate. The characteristic change in the exhaust plasma may mirror that of the processing plasma. If these changes indicate the EPD, the controller 195 may communicate with the processing chamber 110 to end the processing of the substrate (block 470). If the endpoint is not detected, the processing of the substrate may continue (block 480).

In various embodiments, the hyperspectral image collection may be repeated as a cyclic process, alternating the hyperspectral image sources of processing chamber and exhaust chamber. The collected images may be analyzed separately to evaluate the confidence level individually. Alternately, a user may manually switch the hyperspectral image source depending on the type of process and monitoring.

In some embodiments, the hyperspectral images of remote plasma or gas in the remote chamber 180 may be detected and analyzed by the HSI camera 160 before introducing into the processing chamber 110. By analyzing the spectral signatures of the remote plasma or gas, the initial conditions of the processing of the substrate can be precisely characterized, including gas species concentrations, excitation states, and potential contaminants. This detection ensures consistent starting conditions for each process stage, enhancing overall reproducibility.

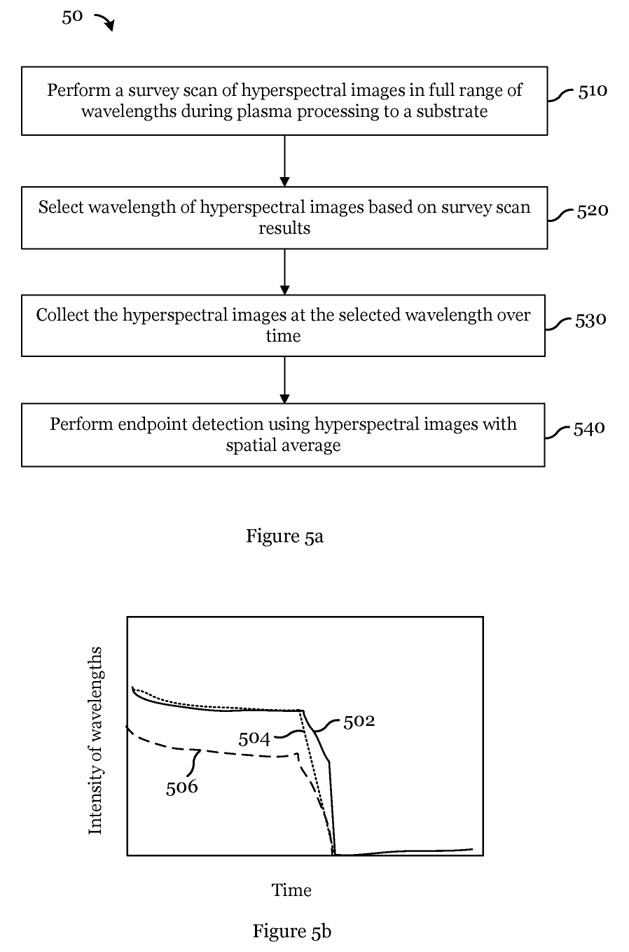

FIGS. 5a-5b illustrate an example process flow chart of processing hyperspectral images in an EPD method and exemplary data illustrating the intensities of selected wavelengths over time, in accordance with an embodiment.

FIG. 5a shows that the process may begin with a comprehensive survey scan, which is performed during plasma processing. This survey is conducted by activating the free-run scanning mode of the interferometer 200 to sequentially transmit different wavelengths. The mode can capture hyperspectral images during a plasma processing before and after the endpoint across the full wavelength range (block 510). In some embodiments, the wavelength ranges from 200 to 900 nm. This extensive scan may serve to build a database of spectral information for similar processes, establishing a baseline for spectral analysis. It identifies key intensity changes at each wavelength that may indicate processing dynamics across various plasma conditions and substrates.

Based on the survey results and database construction, when a specific plasma processing is to be conducted, the method proceeds to select the most relevant wavelength (at least one wavelength) of hyperspectral images for that particular plasma processing (block 520). In various embodiments, the survey results may comprise optical emission properties of the gases or byproducts during the plasma processing. In some embodiments, the wavelength selection prioritizes spectral regions that demonstrated the most significant intensity changes between pre-EPD and post-EPD states during the initial survey scans. This step ensures that the chosen wavelength effectively captures the unique spectral features relevant to a particular plasma process, allowing for precise monitoring and control. In some embodiments, the chosen wavelength may represent the optical emission characteristic wavelength of the etch species or the byproducts. In some embodiments, the system may select and simultaneously monitor multiple wavelengths for subsequent hyperspectral image acquisition and analysis, allowing for a more comprehensive tracking of process dynamics and improved accuracy in endpoint detection.

Subsequently, hyperspectral images may be collected at the selected wavelength(s) over time using a fixed gap non-scanning mode (block 530). In this mode, the interferometer 200 maintains a constant gap between its reflective surfaces to consistently transmit the chosen wavelength. This approach enhances measurement speed and enables real-time plasma monitoring, minimizing the time lag between spectral detection and the ongoing plasma process in the processing chamber 110.

While performing the substrate processing having an end point in the processing chamber 110, the HSI camera 160 may collect the hyperspectral image at the selected wavelength over time during the plasma processing and perform spatial average. The end point may be detected by analyzing temporal intensity changes of one or more selected wavelengths in the processing chamber 110 or the exhaust chamber 165 (block 540). In some embodiments, the endpoint may be determined when the intensities of one or more selected wavelength decrease below predetermined threshold values. FIG. 5b illustrates intensity traces 502, 504, and 506 of three selected wavelengths over time during the plasma processing. In various embodiments, the intensity traces 502, 504, and 506 may exhibit decreases in the intensity when the plasma processing approaches the endpoint. In one or more embodiments, an endpoint may be detected when these intensities fall below predetermined threshold values.

In various embodiments, a ratio of intensities between two wavelengths may be used as the figure of merit, and the endpoint may be detected using the change of the ratio as a function of time. In some embodiments, the endpoint may be detected from a characteristic increase of the ratio of intensities between two wavelengths. In alternative embodiments, the endpoint may be detected from a characteristic decrease of the ratio of intensities between two wavelengths. Such changes in some embodiments may advantageously precede the fall in threshold of raw intensities.

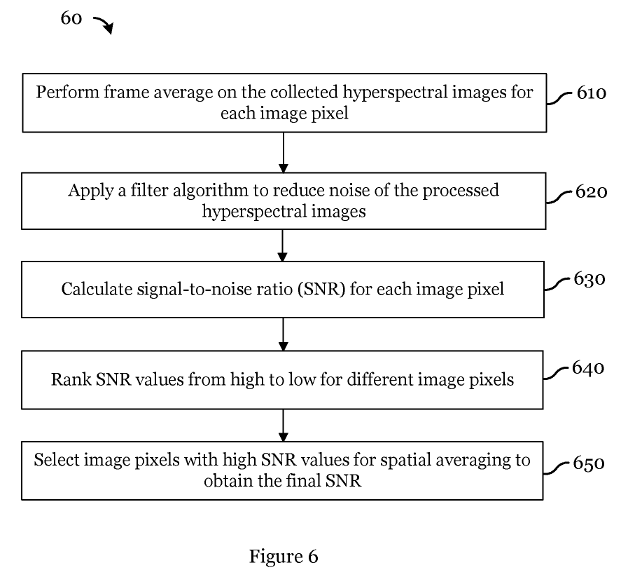

To accurately detect endpoint, high signal-to-noise ratio (SNR) of the hyperspectral images is important, especially for advanced 3D device fabrication. FIG. 6 illustrates an example process flow 60 of a method for enhancing SNR of hyperspectral images, in accordance with an embodiment.

The process flow 60 may begin with performing frame averaging on the collected hyperspectral images for each image pixel (block 610). The frame averaging involves averaging light intensity of multiple consecutive time frames into a single, averaged time frame. A fixed time window for averaging is applied to calculate the average signal. In some embodiments, the time window may range from 10 milliseconds to 200 milliseconds. The frame averaging can reduce random noise while reinforce consistent signal features. This temporal averaging can provide a cleaner baseline for subsequent analysis by improving signal stability and SNR.

Next, a filter algorithm may be applied to further reduce noise in the processed hyperspectral images (block 620). The filter algorithm may comprise Okada filter, median filter, Wiener filter, Gaussian filter, Kalman filter, non-local means filter, or the like. In some embodiments, the filter algorithm may be an Okada filter. The Okada filter may analyze a local neighborhood of pixels and replace the central pixel value with a weighted average of its neighbors. By adjusts weighting based on local intensity gradients, Okada filter may effectively reduce background noise and improve the SNR. This filtering step may further enhance the signal quality before further analysis, particularly in complex plasma environments where subtle spectral changes can indicate plasma processing endpoints.

Following noise reduction, the SNR is calculated for each image pixel (block 630). This step quantifies the quality of the signal for each image pixel in the hyperspectral image, allowing for a comparative analysis of different pixels. The calculated SNR values are then ranked from high to low for different image pixels (block 640). This ranking process may identify the pixels with the strongest and most reliable signals, which are most suitable for accurate endpoint detection.

Based on this ranking, image pixels with high SNR values are selected for spatial averaging for final SNR calculation (block 650). This step can focus the analysis on the most informative regions of the hyperspectral image, thereby achieving high HSI sensitivity for accurate EPD.

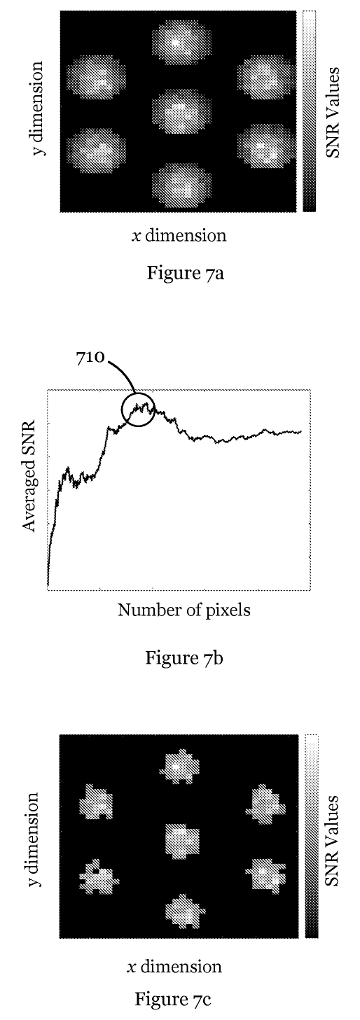

FIGS. 7a-7c illustrates example experimental data showing the distribution of SNR values across different pixels in a hyperspectral image, in accordance with an embodiment.

FIG. 7a may represent block 630, showing an initial SNR spatial distribution across x and y dimensions before the pixel selection. In one embodiment, the data displays hyperspectral images captured through a transparent viewport of a chamber (e.g. a processing chamber or an exhaust chamber). The spatial distribution in FIG. 7a exhibits varying intensities where brighter regions correspond to pixels with higher SNR values. The image reveals distinct regions of high and low SNR values, indicating a broad distribution of signal quality across the measurement area.

FIG. 7b may represent block 640, presenting a quantitative analysis of the SNR distribution, plotting the average SNR against the accumulated number of pixels ranked from highest to lowest SNR values. The circled region 710 represents the selected pixels exhibiting the highest average SNR values, which are prime candidates for spatial averaging and subsequent EPD analysis. By focusing on this number of pixels, the system can maximize the quality and reliability of the spectral data used for EPD. When selecting fewer pixels than the numbers in the circled region 710, the averaged SNR may be lower. Similarly, selecting more pixels beyond these optimal numbers also results in a decreased averaged SNR. This shows that the best SNR may not be achieved by simply increasing the measurement area. In addition, the pixel selection method may not be implemented with a single point spectrometer.

FIG. 7c may represent block 650, showing the spatial distribution after implementing the pixel selection process illustrated in FIG. 7b. In various embodiments, this filtered distribution retains only the number of pixels suggested by the circled region 710. The absence of low-intensity regions in FIG. 7c compared to FIG. 7a demonstrates the effectiveness of the SNR-based pixel selection method described in block 650 of FIG. 6.

Example embodiments of the invention are described below. Other embodiments can also be understood from the entirety of the specification as well as the claims filed herein.

Example 1. A processing system includes a processing chamber configured to hold a substrate to be processed; an exhaust gas line coupled to an exhaust outlet of the processing chamber; an exhaust chamber coupled to the exhaust gas line; a first RF power source coupled to the exhaust chamber, the first RF power source being configured to generate an exhaust plasma in the exhaust chamber from a portion of an exhaust gas; and a hyperspectral imaging (HSI) camera configured to measure a hyperspectral image of the exhaust plasma in the exhaust chamber.

Example 2. The processing system of example 1, where the HSI camera is further configured to measure a hyperspectral image of a gas or plasma in the processing chamber.

Example 3. The processing system of one of examples 1 or 2, further including: a remote chamber coupled to the processing chamber; and a second RF power source coupled to the remote chamber, the second RF power source being configured to generate a remote plasma in the remote chamber.

Example 4. The processing system of one of examples 1 to 3, where the HSI camera is further configured to measure a hyperspectral image of the remote plasma.

Example 5. The processing system of one of examples 1 to 4, further including a gas line connecting the processing chamber and the remote chamber.

Example 6. The processing system of one of examples 1 to 5, further including a controller configured to control operations of the processing chamber, the remote chamber, the first RF power source, and the HSI camera.

Example 7. The processing system of one of examples 1 to 6, where the HSI camera includes: an interferometer configured to filter specific wavelengths of the hyperspectral image of the exhaust plasma; an optical system configured to focus and direct a filtered hyperspectral image of the exhaust plasma; a sensor configured to detect and convert the filtered hyperspectral image of the exhaust plasma to digital data; a non-transitory memory configured to record and store the digital data and a program including instructions; and one or more processors coupled to the non-transitory memory and configured to execute the instructions to process the digital data.

Example 8. The processing system of one of examples 1 to 7, where the interferometer includes a frequency generator, a piezoelectric actuator, and an integrated suite of electronic components including an analog-to-digital converter, a digital signal processor, and communication interfaces for signal generation, acquisition, processing, and data transmission.

Example 9. The processing system of one of examples 1 to 8, where the optical system includes a plurality of lenses and mirrors configured to focus and direct the filtered hyperspectral image of the exhaust plasma to optimize signal path efficiency and image clarity.

Example 10. The processing system of one of examples 1 to 9, where the sensor includes a plurality of charge-coupled device (CCD) sensors and complementary metal-oxide-semiconductor (CMOS) sensors.

Example 11. The processing system of one of examples 1 to 10, further including a non-transitory memory storing a program to be executed in the controller, where the program includes instructions, when executed by the controller, enable the controller to perform an endpoint detection (EPD) of a process in the processing chamber based on the hyperspectral image of the exhaust plasma.

Example 12. A method of processing a substrate includes processing a substrate by exposing the substrate in a processing chamber; removing an exhaust gas from the processing chamber to an exhaust gas line; generating an exhaust plasma in an exhaust chamber from the exhaust gas, the exhaust chamber connecting to the processing chamber through the exhaust gas line; detecting a hyperspectral image from the exhaust plasma using a hyperspectral imaging (HSI) camera; and performing an endpoint detection (EPD) of the processing of the substrate based on the hyperspectral image.

Example 13. The method of example 12, where detecting the hyperspectral image includes continuously detecting the hyperspectral image of the exhaust plasma over a period of time of the processing of the substrate.

Example 14. The method of one of examples 12 or 13, where detecting the hyperspectral image includes periodically detecting the hyperspectral image of the exhaust plasma over a period of time of the processing of the substrate.

Example 15. The method of one of examples 12 to 14, further including: detecting a hyperspectral image of a plasma or gas in the processing chamber using the HSI camera; and performing an EPD of the plasma processing based on the hyperspectral image of the plasma or gas in the processing chamber.

Example 16. The method of one of examples 12 to 15, further including: generating a remote plasma in a remote chamber; removing the remote plasma from the remote chamber to the processing chamber; and detecting a hyperspectral image of the remote plasma using the HSI camera.

Example 17. The method of one of examples 12 to 16, further including simultaneously or alternatively detecting of the hyperspectral images of the exhaust plasma, the remote plasma, or the plasma or gas in the processing chamber by the HSI camera.

Example 18. A method of endpoint detection (EPD) based on a hyperspectral image, the method includes performing a survey scan of a hyperspectral image across a full range of wavelengths during plasma processing a substrate to establish a baseline spectral database; selecting at least one wavelength of the hyperspectral image for a plasma processing based on optical emission properties of gases or byproducts during the plasma processing; and while performing a process having an end point in a processing chamber, collecting the hyperspectral image at the selected wavelength over time during the plasma processing; and detecting the end point of the process based on changes of the collected hyperspectral image.

Example 19. The method of example 18, further including enhancing signal-to-noise ratio (SNR) of the collected hyperspectral image by: performing a frame average at a fixed time duration over each image pixel of the hyperspectral images; applying a filter algorithm to reduce noise of the frame averaged hyperspectral images; calculating SNR for each image pixel; ranking SNR values from high to low for different image pixels; selecting image pixels with high SNR values for spatial averaging; and calculating a final SNR based on the selected image pixels.

Example 20. The method of one of examples 18 or 19 where the filter algorithm includes Okada filter, median filter, Wiener filter, Gaussian filter, Kalman filter, or non-local means filter.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A processing system comprising:
a processing chamber configured to hold a substrate to be processed;
an exhaust gas line coupled to an exhaust outlet of the processing chamber;
an exhaust chamber coupled to the exhaust gas line;
a first RF power source coupled to the exhaust chamber, the first RF power source being configured to generate an exhaust plasma in the exhaust chamber from a portion of an exhaust gas; and
a hyperspectral imaging (HSI) camera configured to measure a hyperspectral image of the exhaust plasma in the exhaust chamber.

2. The processing system of claim 1, wherein the HSI camera is further configured to measure a hyperspectral image of a gas or plasma in the processing chamber.

3. The processing system of claim 2, further comprising:
a remote chamber coupled to the processing chamber; and
a second RF power source coupled to the remote chamber, the second RF power source being configured to generate a remote plasma in the remote chamber.

4. The processing system of claim 3, wherein the HSI camera is further configured to measure a hyperspectral image of the remote plasma.

5. The processing system of claim 3, further comprising a gas line connecting the processing chamber and the remote chamber.

6. The processing system of claim 4, further comprising a controller configured to control operations of the processing chamber, the remote chamber, the first RF power source, and the HSI camera.

7. The processing system of claim 1, wherein the HSI camera comprises:
an interferometer configured to filter specific wavelengths of the hyperspectral image of the exhaust plasma;
an optical system configured to focus and direct a filtered hyperspectral image of the exhaust plasma;
a sensor configured to detect and convert the filtered hyperspectral image of the exhaust plasma to digital data;
a non-transitory memory configured to record and store the digital data and a program comprising instructions; and
one or more processors coupled to the non-transitory memory and configured to execute the instructions to process the digital data.

8. The processing system of claim 7, wherein the interferometer comprises a frequency generator, a piezoelectric actuator, and an integrated suite of electronic components comprising an analog-to-digital converter, a digital signal processor, and communication interfaces for signal generation, acquisition, processing, and data transmission.

9. The processing system of claim 7, wherein the optical system comprises a plurality of lenses and mirrors configured to focus and direct the filtered hyperspectral image of the exhaust plasma to optimize signal path efficiency and image clarity.

10. The processing system of claim 7, wherein the sensor comprises a plurality of charge-coupled device (CCD) sensors and complementary metal-oxide-semiconductor (CMOS) sensors.

11. The processing system of claim 6, further comprising a non-transitory memory storing a program to be executed in the controller, wherein the program comprises instructions, when executed by the controller, enable the controller to perform an endpoint detection (EPD) of a process in the processing chamber based on the hyperspectral image of the exhaust plasma.

12. A method of processing a substrate, the method comprising:
processing a substrate by exposing the substrate in a processing chamber;
removing an exhaust gas from the processing chamber to an exhaust gas line;
generating an exhaust plasma in an exhaust chamber from the exhaust gas, the exhaust chamber connecting to the processing chamber through the exhaust gas line;
detecting a hyperspectral image from the exhaust plasma using a hyperspectral imaging (HSI) camera; and
performing an endpoint detection (EPD) of the processing of the substrate based on the hyperspectral image.

13. The method of claim 12, wherein detecting the hyperspectral image comprises continuously detecting the hyperspectral image of the exhaust plasma over a period of time of the processing of the substrate.

14. The method of claim 12, wherein detecting the hyperspectral image comprises periodically detecting the hyperspectral image of the exhaust plasma over a period of time of the processing of the substrate.

15. The method of claim 12, further comprising:
detecting a hyperspectral image of a plasma or gas in the processing chamber using the HSI camera; and
performing an EPD of the plasma processing based on the hyperspectral image of the plasma or gas in the processing chamber.

16. The method of claim 15, further comprising:
generating a remote plasma in a remote chamber;
removing the remote plasma from the remote chamber to the processing chamber; and
detecting a hyperspectral image of the remote plasma using the HSI camera.

17. The method of claim 16, further comprising simultaneously or alternatively detecting of the hyperspectral images of the exhaust plasma, the remote plasma, or the plasma or gas in the processing chamber by the HSI camera.

18. A method of endpoint detection (EPD) based on a hyperspectral image, the method comprising:
performing a survey scan of a hyperspectral image across a full range of wavelengths during plasma processing a substrate to establish a baseline spectral database;
selecting at least one wavelength of the hyperspectral image for a plasma processing based on optical emission properties of gases or byproducts during the plasma processing; and
while performing a process having an end point in a processing chamber,
collecting the hyperspectral image at the selected wavelength over time during the plasma processing; and
detecting the end point of the process based on changes of the collected hyperspectral image.

19. The method of claim 18, further comprising enhancing signal-to-noise ratio (SNR) of the collected hyperspectral image by:
performing a frame average at a fixed time duration over each image pixel of the hyperspectral images;
applying a filter algorithm to reduce noise of the frame averaged hyperspectral images;
calculating SNR for each image pixel;
ranking SNR values from high to low for different image pixels;
selecting image pixels with high SNR values for spatial averaging; and
calculating a final SNR based on the selected image pixels.

20. The method of claim 19 wherein the filter algorithm comprises Okada filter, median filter, Wiener filter, Gaussian filter, Kalman filter, or non-local means filter.
